(19) United States
(12) Patent Application Publication
(10) Pub. No.: US 2020/0224319 A1
(43) Pub. Date: Jul. 16, 2020

(54) FLEXIBLE HARD COMPOSITE COATING, PREPARATION METHOD THEREOF, AND COATED CUTTER

(71) Applicant: LINGNAN NORMAL UNIVERSITY, Guangdong (CN)

(72) Inventors: Changwei ZOU, Guangdong (CN); Shimin CHEN, Guangdong (CN); Feng LIANG, Guangdong (CN)

(21) Appl. No.: 16/651,080

(22) PCT Filed: Sep. 25, 2018
(86) PCT No.: PCT/CN2018/107205

§ 371 Date: Mar. 26, 2020

(30) Foreign Application Priority Data
Oct. 10, 2017 (CN) 201710934485.5

(51) Int. Cl. C23C 28/00; C23C 28/04; C23C 14/35; C23C 14/06

(52) U.S. Cl. CPC C23C 28/42; C23C 28/044; C23C 14/0676; C23C 14/0641; C23C 14/35

(57) ABSTRACT

The present invention provides a flexible hard composite coating, a preparation method thereof and a coated cutter. The flexible hard composite coating includes an AlCrN transition layer and a nanocomposite layer sequentially disposed on the surface of a substrate, the nanocomposite layer having CrON layers and AlON layers sequentially alternately arranged on the surface of the AlCrN transition layer. According to an embodiment, AlCrN is used as a transition layer, for strengthening the connection between the nanocomposite layer and the substrate. The nanocomposite layer constituted by the CrON layers and the AlON layers increases the toughness of the coating and the successive alternation of the CrON layers and the AlON layers reduces the stress of the coating, increasing the crystal plane structure and the grain boundary of the coating and further improves the properties of hardness and resistance to high-temperature oxidation.

### CROSS REFERENCE TO RELATED APPLICATIONS

This application claims priority to Chinese Patent Application No. 201710934485.5 entitled “FLEXIBLE HARD COMPOSITE COATING, PREPARATION METHOD THEREOF, AND COATED CUTTER”, filed before China's State Intellectual Property Office on Oct. 10, 2017, the entire contents of which are incorporated herein by reference.

### TECHNICAL FIELD

The present invention relates to the technical field of hard coatings, and particularly relates to a flexible hard composite coating, a preparation method thereof and a coated cutter.

### BACKGROUND

Hard coating is an effective way for performing material surface strengthening, exerting material potential and increasing production efficiency, is a kind of surface coating, and refers to a surface coating which is deposited on the surface of a substrate by a physical or chemical method and has microhardness greater than a certain special value. Hard coating has been widely applied to the cutting industry, die industry, geological drilling, textile industry, machinery manufacturing and aerospace field, and plays a more and more important role. Application of the hard coating in the cutting industry not only includes machining of common cutting tools, such as cutters, drill bits and other hard-to-machine materials, but also may increase cutting precision, exerts the advantages of being superhard, tough, wear-resistant, self-lubricating and the like, and thus is regarded as a revolution of the cutting history.

Hard nanocomposite coating is a representative of a new generation of coating, being typically represented by a binary nc-TiN/a-Si₃N₄ hard composite coating, with advantage focused on promotion of hardness of coatings, so that a coating acquires hardness as high as possible. Nanocomposite coatings with hardness H>40 GPa is generally called as a superhard nanocomposite coating in the field of film coating. Currently, hardness of mainly two major kinds of binary nanocomposite coatings may be promoted, hard alloy phase/hard phase nanocomposite coating and hard phase/soft phase nanocomposite coating.

However, promotion of hardness is not a sole indicator for estimating a hard nanocomposite coating, and it is more important to improve the toughness of a coating than purchasing higher hardness for many application occasions. However, superhard materials are generally fragile, hardly generate plastic deformation, and thus lose efficacy in a very small strain condition. For example, in existing coatings, hardness of superhard nanocomposite coatings, such as TiSiN, TiSiAlN, nc-TiN/a-Si₃N₄ coatings are very high, but toughness is poor, and plastic deformation is small, and thus are liable to crack; while macromolecule organic materials are good in plasticity, but are poor in hardness, and are not suitable for the requirement of high-speed machining. Therefore, it is a current research focus of hard coatings to improve the toughness of hard coatings, so that the hard coatings are hard to generate cracks in a high strain condition, to meet most application requirements.

### SUMMARY

The present invention is directed to provide a flexible hard composite coating, a preparation method thereof and a coated cutter. A flexible hard composite coating provided by the present invention has good hardness and toughness.

In order to solve the foregoing technical problem, a technical scheme adopted by the present invention is:

a flexible hard composite coating, including an AlCrN transition layer and a nanocomposite layer sequentially disposed on the surface of a substrate, the nanocomposite layer comprising CrON layers and AlON layers sequentially alternately arranged on the surface of the AlCrN transition layer.

Optimally, thickness of each CrON layer and thickness of each AlON layer are independently 3˜20 nm respectively.

Optimally, quantity of the CrON layers is 10˜50.

Optimally, the CrON layer contains 34˜45 at. % of chromium, 12˜18 at. % of oxygen and 40˜50 at. % of nitrogen according to atomic percent.

Optimally, the CrON layer includes a CrN nanocrystalline and Cr₂O₃ amorphous nanocomposite structure.

Optimally, the AlON layer contains 35˜43 at. % of aluminium, 10˜20 at. % of oxygen and 38˜48 at. % of nitrogen according to atomic percent.

Optimally, the AlON layer includes an AIN nanocrystalline and Al₂O₃ amorphous nanocomposite structure.

Optimally, thickness of the AlCrN transition layer is 200˜500 nm.

The present invention provides a preparation method of the flexible hard composite coating according to the foregoing scheme, including the following steps:

(1) depositing an AlCrN transition layer on the surface of a substrate; and

(2) sequentially alternately depositing CrON layers and AlON layers on the surface of the AlCrN transition layer in step (1), to obtain a flexible hard composite coating.

Optimally, deposition in step (1) and step (2) is high power pulse magnetron sputtering deposition.

The present invention also provides a coated cutter, including a cutter substrate and a coating disposed on the surface of the cutter substrate, the coating being a flexible hard composite coating according to the foregoing technical scheme or a flexible hard composite coating prepared by a preparation method according to according to the foregoing scheme.

The flexible hard composite coating provided by the present invention includes an AlCrN transition layer and a nanocomposite layer sequentially disposed on the surface of a substrate. The nanocomposite layer includes CrON layers and AlON layers sequentially alternately arranged on the surface of the AlCrN transition layer. In the present invention, AlCrN is used as a transition layer, for strengthening a binding force between the nanocomposite layer and the substrate; the nanocomposite layer constituted by the CrON layers. The AlON layers increases the toughness of the coating and the successive alternation of the CrON layers, and the AlON layers reduces the stress of the coating, increasing the crystal plane structure and the grain boundary of the coating and further improving the properties of hardness and resistance to high-temperature oxidation. Experimental results clearly indicate that the hardness of the flexible hard composite coating provided by the present invention may reach 28 GPa and the elastic recovery coefficient may reach 70%.

### BRIEF DESCRIPTION OF THE DRAWINGS

FIG. 1 is a schematic structure diagram of a flexible hard composite coating of the present invention, wherein 1 is a substrate, 2 is an AlCrN transition layer, and 3 is a nanocomposite layer;

FIG. 2 is a schematic structure diagram of a flexible hard composite coating of the present invention, wherein 1 is a substrate, 2 is an AlCrN transition layer, 3 is a nanocomposite layer, 4 is a CrON layer and 5 is an AlON layer;

FIG. 3 is a TEM diagram of a nanocomposite layer in the flexible hard composite coating in embodiment 2 of the present invention; and

FIG. 4 is a selected area electron diffraction diagram of a nanocomposite layer in the flexible hard composite coating in embodiment 2 of the present invention.

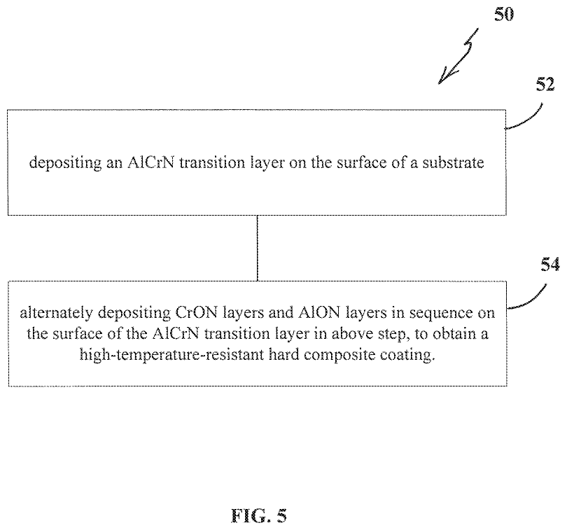

### DESCRIPTION OF THE EMBODIMENTS

The following further describes the present invention in combination with embodiments and drawings.

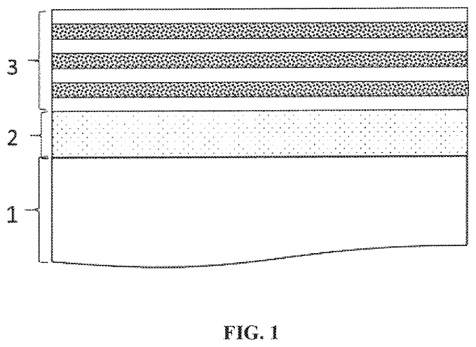

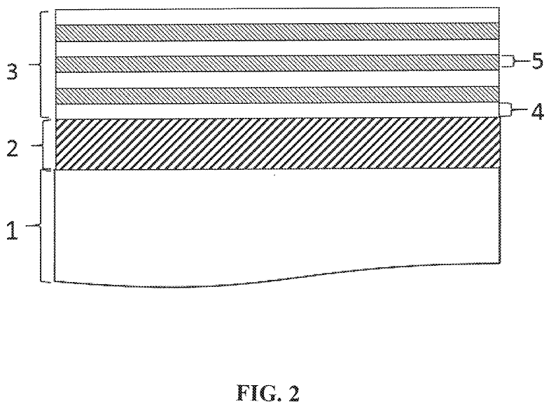

The present invention provides a flexible hard composite coating, as shown in FIG. 1 and FIG. 2. The flexible hard composite coating provided by the present invention includes an AlCrN transition layer 2 and a nanocomposite layer 3 sequentially disposed on the surface of a substrate 1. The nanocomposite layer 3 includes CrON layers 4 and AlON layers 5 which are sequentially alternately arranged.

The flexible hard composite coating provided by the present invention includes an AlCrN transition layer disposed on the surface of a substrate. According to the present invention, the thickness of the AlCrN transition layer is optimally 200˜500 nm, more optimally, 300˜400 nm, and most optimally, 340˜360 nm. According to the present invention, the AlCrN transition layer can improve a binding force between a nanocomposite layer and a substrate, improve the use effect of a coating and prolong the service life of the coating.

The flexible hard composite coating provided by the present invention includes a nanocomposite layer disposed on the surface of an AlCrN transition layer, the nanocomposite layer including CrON layers and AlON layers sequentially alternately arranged on the surface of the AlCrN transition layer. According to the present invention, an outermost layer of the flexible hard composite coating is optimally an AlON layer. According to the present invention, thickness of each CrON layer and thickness of each AlON layer are independently 3˜20 nm respectively, more optimally, 5˜15 nm, most optimally, 8˜12 nm. According to the present invention, quantity of the CrON layers is 10˜50, more optimally, 20˜40, most optimally, 25˜35.

According to the present invention, the CrON layer contains 34˜45 at. % of chromium, 12˜18 at. % of oxygen and 40˜50 at. % of nitrogen according to atomic percent, more optimally, contains 38˜42 at. % of chromium, 14˜16 at. % of oxygen and 42˜48 at. % of nitrogen, most optimally, contains 40 at. % of chromium, 15 at. % of oxygen and 45 at. % of nitrogen. According to the present invention, the CrON layer optimally includes a CrN nanocrystalline and Cr₂O₃ amorphous nanocomposite structure. According to the present invention, the grain size of the CrON layers is optimally 2˜10 nm, more optimally, 3˜6 nm. According to the present invention, the CrON layers have excellent oxidation resistance and toughness, and meanwhile has high hardness and thermal stability.

According to the present invention, the AlON layer contains 35˜43 at. % of aluminium, 10˜20 at. % of oxygen and 38˜48 at. % of nitrogen according to atomic percent, more optimally, contains 38˜42 at. % of aluminium, 12˜18 at. % of oxygen and 40˜46 at. % of nitrogen, most optimally, contains 40 at. % of aluminium, 15 at. % of oxygen and 45 at. % of nitrogen. According to the present invention, the AlON layer includes an AIN nanocrystalline and Al₂O₃ amorphous nanocomposite structure. According to the present invention, the grain size of the AlON layers is optimally, 3˜12 nm, more optimally, 4˜6 nm. According to the present invention, the AlON layers have excellent oxidation resistance and toughness, and meanwhile has high hardness and thermal stability.

According to the present invention, the CrON layers and the AlON layers are periodically arranged alternately, so as to reduce stress of a coating, increase the crystal plane structure and the grain boundary of the coating and further improve the properties of hardness and resistance to high-temperature oxidation. According to the present invention, the high-temperature stability of the flexible hard composite coating is higher than 1000° C., more optimally, 1200˜1500° C. According to the present invention, the CrON layers and the AlON layers are alternately arranged, the outermost layer of the composite coating is changed along with the change of the thickness of the coating, and the outermost layer may be a CrON layers, and may be also an AlON layer.

The present invention also provides a preparation method of the flexible hard composite coating according to the foregoing scheme, including the following steps:

(1) depositing an AlCrN transition layer on the surface of a substrate; and

(2) sequentially alternately depositing CrON layers and AlON layers on the surface of the AlCrN transition layer in step (1), to obtain a flexible hard composite coating.

According to the present invention, an AlCrN transition layer is deposited on the surface of a substrate. According to the present invention, material of the substrate is optimally hard alloy or high-speed steel, more optimally, hard alloy. There is no special limitation to components of the hard alloy or high-speed steel in the present invention, just hard alloy or high-speed steel familiar to technicians of the field and used for machining may be adopted.

According to the present invention, deposition of the AlCrN transition layer is optimally high power pulse magnetron sputtering deposition. There is no special limitation to the operation of high power pulse magnetron sputtering deposition of the AlCrN transition layer, just a technical scheme of high power pulse magnetron sputtering deposition familiar to technicians of the field may be adopted.

According to the present invention, before deposition of the AlCrN transition layer, optimally, pretreatment, sputtering cleaning and activation are sequentially performed on the substrate. There is no special limitation to operation of the pretreatment, just a technical scheme for pretreatment familiar to a technician of the field may be adopted. According to the present invention, optimally, the pretreatment sequentially includes washing and drying. According to the present invention, the washing optimally includes ultrasonic treatment sequentially performed in acetone and absolute ethyl alcohol; time for ultrasonic treatment sequentially performed in acetone and absolute ethyl alcohol is optimally independently 10˜20 min, more optimally, 15 min. According to the present invention, the drying is optimally drying with clean compressed air.

According to the present invention, parameters of the sputtering cleaning are optimally: substrate revolving speed being 2˜8 rpm, sputtering temperature being 300˜500° C., sputtering gas being argon, sputtering gas pressure being 0.3˜1.0 Pa, bias voltage being 800˜1200V, and sputtering cleaning time being 10˜30 min, more optimally: substrate revolving speed being 4˜6 rpm, sputtering temperature being 350˜450° C., sputtering gas being argon, sputtering gas pressure being 0.5˜0.8 Pa, bias voltage being 900˜1100V, and sputtering cleaning time being 15˜25 min. According to the present invention, the sputtering cleaning can improve a binding capacity between a substrate and an AlCrN transition layer.

According to the present invention, optimally, after the sputtering cleaning is completed, opening a Cr target directly and adjusting all parameters to activating parameters to perform activation. According to the present invention, the activating parameters are optimally: substrate revolving speed being 2˜8 rpm, sputtering temperature being 300˜500° C., sputtering gas being argon, sputtering gas pressure being 0.3˜1.0 Pa, bias voltage being 300˜500V, average target material current being 2˜10 A, target material peak current being 400˜800 A, target material peak voltage being 500˜900V, duty ratio being 2˜7%, and sputtering cleaning time being 5˜15 min, more optimally are: substrate revolving speed being 4˜6 rpm, sputtering temperature being 350˜450° C., sputtering gas being argon, sputtering gas pressure being 0.5˜0.8 Pa, bias voltage being 350˜450V, average target material current being 4˜8 A, target material peak current being 500˜700 A, target material peak voltage being 600˜800V, duty ratio being 3˜5%, and sputtering cleaning time being 8˜12 min. According to the present invention, the activation increases an energy state of particles on the surface of a substrate by bombarding the surface of the substrate with Cr ions, to generate a metal layer, and strengthen a binding force between a coating and a substrate.

According to the present invention, optimally, after the activation is completed, opening a Cr target and an Al target directly and adjusting all parameters to parameters for high power pulse magnetron sputtering deposition of an AlCrN transition layer to perform deposition of the AlCrN transition layer. According to the present invention, parameters for high power pulse magnetron sputtering deposition of an AlCrN transition layer are optimally: substrate revolving speed being 2˜8 rpm, sputtering temperature being 300˜500° C., sputtering gas being argon, reaction gas being nitrogen, sputtering gas pressure being 0.6˜1.2 Pa, bias voltage being 100˜150V, target material peak current being 400˜800 A, target material peak voltage being 400˜700V, duty ratio being 3˜7%, and sputtering cleaning time being 5˜20 min, more optimally are: substrate revolving speed being 4˜6 rpm, sputtering temperature being 350˜450° C., sputtering gas being argon, reaction gas being nitrogen, sputtering gas pressure being 0.5˜0.8 Pa, bias voltage being 350˜450V, target material peak current being 450˜550 A, target material peak voltage being 500˜600V, duty ratio being 4˜6%, and sputtering cleaning time being 10˜15 min.

After obtaining an AlCrN transition layer, according to the present invention, CrON layers and AlON layers are sequentially alternately deposed on the surface of the AlCrN transition layer, to obtain a flexible hard composite coating. According to the present invention, deposition of the AlON layers and the CrON layers is optimally high power pulse magnetron sputtering deposition. According to the present invention, the high power pulse magnetron sputtering deposition can further cause a coating to have an excellent film substrate binding force, so as to reduce internal stress of the coating and improve the crack-resistant performance.

According to the present invention, optimally, after deposition of the AlCrN transition layer is completed, closing an Al target, opening a Cr target, and adjusting parameters to parameters for high power pulse magnetron sputtering deposition of CrON layers to perform deposition, then closing the Cr target, opening the Al target, and adjusting parameters to parameters for high power pulse magnetron sputtering deposition of AlON layers to perform deposition, alternately opening and closing the Cr target and the Al target, until completing deposition of the nanocomposite layer.

According to the present invention, parameters for high power pulse magnetron sputtering deposition of the CrON layers and the AlON layers are optimally independently: sputtering gas being argon, reaction gases being oxygen and nitrogen, total gas pressure of argon and oxygen being 0.4˜1.2 Pa, gas pressure ratio between nitrogen and oxygen being (1˜3):(3˜1), substrate revolving speed being 2˜10 rpm, sputtering temperature being 300˜500° C., average target material current being 3˜8 A, target material peak current being 400˜900 A, target material peak voltage being 400˜800V, duty ratio being 2˜8%, and sputtering cleaning time being 1˜8 min, more optimally are: sputtering gas being argon, reaction gases being oxygen and nitrogen, total gas pressure of argon and oxygen being 0.6˜1.0 Pa, gas pressure ratio between nitrogen and oxygen being (1˜2):(2˜1), substrate revolving speed being 4˜6 rpm, sputtering temperature being 350˜450° C., average target material current being 4˜6 A, target material peak current being 500˜700 A, target material peak voltage being 500˜700V, duty ratio being 4˜6%, and sputtering cleaning time being 3˜5 min.

According to the present invention, optimally, after deposition of the nanocomposite layer is completed, cooling a product of the deposition, to obtain a flexible hard composite coating. According to the present invention, the cooling is optimally performed in an atmosphere of depositing. According to the present invention, the cooling final temperature of the product of the deposition in the atmosphere of depositing is optimally below 150° C., more optimally, below 80° C.

The present invention also provides a coated cutter, including a cutter substrate and a coating disposed on the surface of the cutter substrate, the coating being a flexible hard composite coating according to the foregoing technical scheme or a flexible hard composite coating prepared by a preparation method according to according to the foregoing scheme. According to the present invention, the material of the cutter substrate is optimally hard alloy or high-speed steel. There is no special limitation to components of the hard alloy or high-speed steel in the present invention, just hard alloy or high-speed steel familiar to technicians of the field and used for machining may be adopted. There is no special limitation to the shape and size of the cutter substrate, just a cutter familiar to a technician of the field may be adopted.

According to the present invention, the coated cutter is optimally prepared by taking a cutter substrate as a substrate and preparing according to a preparation method of the flexible hard composite coating according to the foregoing technical scheme, which is not further described herein.

The following describes a flexible hard composite coating, a preparation method thereof and a coated cutter provided by the present invention in details in combination with embodiments, but they cannot be understood as limitation to the protection scope of the present invention.

### Embodiment 1

Uniformly fixing a hard alloy cutter substrate after pretreatment on a support, putting into a coating machine, adjusting the revolving speed of a workpiece support to 2 rpm, vacuumizing until ultimate pressure is 1.0×10⁻³ Pa, meanwhile, starting a heater, rising temperature to 300° C.; opening an argon flow valve, adjusting a vacuum chamber to be about 0.5 Pa, and applying negative bias voltage 800 V to the substrate, to perform glow sputtering cleaning for 10 min;

then reducing negative bias voltage of the substrate to 300V, starting a high power pulse magnetron sputtering pure Cr target, adjusting average target material current to 2 A, peak current to 400V, peak voltage to 600V, and duty ratio to 3%, and bombarding the substrate for 5 min at high energy with Cr ions to activate the surface of the substrate;

opening a nitrogen flow valve, reducing substrate bias voltage to 100V, opening an Al target and an Cr target at the same time under conditions that film coating pressure is 0.6 Pa and temperature is 300° C., controlling peak current at 400 A, peak voltage at 400V, and duty ratio at 3%, and depositing an AlCrN transition layer for 5 min; and

introducing argon and oxygen, controlling total gas pressure at 0.4 Pa, with argon/oxygen ratio of 1/3 and workpiece support revolving speed of 2 rpm, alternately opening the Cr target and the Al target, adjusting high power pulse magnetron sputtering average current to 3 A, peak current to 400 A, peak voltage to 400V, and duty ratio to 2%, depositing a CrON/AlON layer for 4 min, turning off a power source, closing a flow valve, taking out the substrate after being cooled to 80° C. along with a furnace and then cooling at normal temperature.

A coating on the surface of a prepared sample is named as coating 1, with atomic percent and thickness of each layer as follows:

an aluminum-chromium-nitrogen transition layer: aluminum: 16 at. %, chromium: 28 at. %, nitrogen: 56 at. %; thickness: 200 nm;

an aluminum-oxygen-nitrogen coating: aluminum: 37 at. %, oxygen: 17 at. %, nitrogen: 46 at. %; thickness: 3 nm; and

a chromium-oxygen-nitrogen coating: chromium: 34 at. %, oxygen: 18 at. %, nitrogen: 48 at. %; thickness: 5 nm.

### Embodiment 2

Uniformly fixing a high-speed steel cutter substrate after pretreatment on a support, putting into a coating machine, adjusting the revolving speed of a workpiece support to 8 rpm, vacuumizing until ultimate pressure is 5.0×10⁻³ Pa, meanwhile, starting a heater, and rising temperature to 500° C.;

opening an argon flow valve, adjusting a vacuum chamber to be about 1.0 Pa, and applying negative bias voltage 1200 V to the substrate, to perform glow sputtering cleaning for 30 min; then reducing negative bias voltage of the substrate to 500V, starting a high power pulse magnetron sputtering pure Cr target, adjusting average target material current to 10 A, peak current to 800V, peak voltage to 800V, and duty ratio to 7%, and bombarding the substrate for 15 min at high energy with Cr ions to activate the surface of the substrate;

opening a nitrogen flow valve, reducing substrate bias voltage to 150V, opening an Al target and an Cr target at the same time under conditions that film coating pressure is 1.2 Pa and temperature is 500° C., controlling peak current at 600 A, peak voltage at 700V, and duty ratio at 8%, and depositing an AlCrN transition layer for 20 min; and

introducing argon and oxygen, controlling total gas pressure at 1.2 Pa, with nitrogen/oxygen ratio of 3/1 and workpiece support revolving speed of 10 rpm, alternately opening the Cr target and the Al target, adjusting high power pulse magnetron sputtering average current to 8 A, peak current to 900 A, peak voltage to 800V, and duty ratio to 8%, depositing a CrON/AlON layer for 200 min, turning off a power source, closing a flow valve, taking out the substrate after being cooled to 150° C. along with a furnace and then cooling at normal temperature.

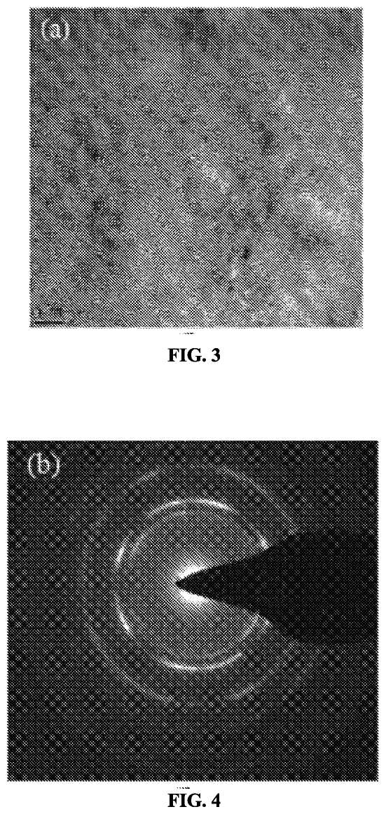

A coating on the surface of a prepared sample is named as coating 2, the high resolution transmission electron microscope and selected area electron diffraction images of the coating are as shown in FIG. 2 and FIG. 3[JT1], electron diffraction rings of nanocrystalline CrN and AlN may be obviously seen, and diffraction rings of Al₂O₃ and Cr₂O₃ are not found, speculating that it is an amorphous phase, therefore, an overall coating is of a nanocomposite structure with nanocrystalline being inlaid in an amorphous matrix.

Atomic percent and thickness of the coating are as follows:

an aluminum-chromium-nitrogen transition layer: aluminum: 20 at. %, chromium: 31 at. %, nitrogen: 49 at. %; thickness: 320 nm;

an aluminum-oxygen-nitrogen coating: aluminum: 39 at. %, oxygen: 14 at. %, nitrogen: 47 at. %; thickness: 6 nm; and

a chromium-oxygen-nitrogen coating: chromium: 45 at. %, oxygen: 11 at. %, nitrogen: 44 at. %; thickness: 8 nm.

### Embodiment 3

Uniformly fixing a hard alloy cutter substrate after pretreatment on a support, putting into a coating machine, adjusting the revolving speed of a workpiece support to 4 rpm, vacuumizing until ultimate pressure is 2.0×10⁻³ Pa, meanwhile, starting a heater, and rising temperature to 400° C.;

opening an argon flow valve, adjusting a vacuum chamber to be about 0.8 Pa, and applying negative bias voltage 1000 V to the substrate, to perform glow sputtering cleaning for 20 min; then reducing negative bias voltage of the substrate to 400V, starting a high power pulse magnetron sputtering pure Cr target, adjusting average target material current to 4 A, peak current to 500V, peak voltage to 520V, and duty ratio to 3%, and bombarding the substrate for 10 min at high energy with Cr ions to activate the surface of the substrate;

opening a nitrogen flow valve, reducing substrate bias voltage to 120V, opening an Al target and an Cr target at the same time under conditions that film coating pressure is 0.8 Pa and temperature is 500° C., controlling peak current at 400 A, peak voltage at 450V, and duty ratio at 3%, depositing an AlCrN transition layer for 10 min, introducing argon and oxygen, controlling total gas pressure at 0.8 Pa, with nitrogen/oxygen ratio of 1/1 and workpiece support revolving speed of 4 rpm, alternately opening the Cr target and the Al target, adjusting high power pulse magnetron sputtering average current to 4 A, peak current to 400 A, peak voltage to 400V, and duty ratio to 3%, depositing a CrON/AlON layer for 100 min, turning off a power source, closing a flow valve, taking out the substrate after being cooled to 100° C. along with a furnace and then cooling at normal temperature.

A coating on the surface of a prepared sample is named as coating 3, with atomic percent and thickness of the coating as follows:

an aluminum-chromium-nitrogen transition layer: aluminum: 21 at. %, chromium: 34 at. %, nitrogen: 45 at. %; thickness: 400 nm;

an aluminum-oxygen-nitrogen coating: aluminum: 41 at. %, oxygen: 16 at. %, nitrogen: 43 at. %; thickness: 12 nm; and

a chromium-oxygen-nitrogen coating: chromium: 39 at. %, oxygen: 17 at. %, nitrogen: 44 at. %; thickness: 6 nm.

### Comparative Example 1

A sample only containing an aluminum-chromium-nitrogen buffer layer and prepared on a hard alloy substrate by adopting a method described in embodiment 1, named as coating 4.

### Comparative Example 2

A sample only containing an aluminum-chromium-nitrogen buffer layer and an aluminum-oxygen-nitrogen coating and prepared on a hard alloy substrate by adopting a method described in embodiment 1, named as coating 5.

### Comparative Example 3

A sample only containing an aluminum-chromium-nitrogen buffer layer and a chromium-oxygen-nitrogen coating and prepared on a hard alloy substrate by adopting a method described in embodiment 1, named as coating 6.

Performances of coatings obtained in embodiments 1˜3 and comparative examples 1˜3 are detected, results being as shown in table 1.

TABLE 1
Performance detection results of coatings of embodiments
1~3 and comparative examples 1~3

| | Hardness | Binding force | Elastic |
|---|---|---|---|
| Number | (GPa) | (N) | recovery rate |
| Coating 1 | 24 | 63 | 68% |
| Coating 2 | 28 | 60 | 70% |
| Coating 3 | 24 | 65 | 62% |
| Coating 4 | 5 | 58 | 45% |
| Coating 5 | 7 | 50 | 44% |
| Coating 6 | 10 | 57 | 48% |

It is known from the foregoing comparative examples and embodiments that the flexible hard composite coating provided by the present invention is high in hardness, good in flexibility, and strong in binding force with a substrate.

Descriptions of the foregoing embodiments are merely used for helping to understand the method of the present invention and the core thought thereof. It should be noted that a person of ordinary skill in the art may make some improvements and modifications without departing from the principle of the invention, and these improvements and modifications all fall within the protection scope of the present invention. Various modifications to these embodiments are apparent to professionals of the art, and a general principle defined herein may be implemented in other embodiments under the condition of not departing from the spirit or scope of the present invention. Therefore, the present invention will not be limited to these embodiments shown herein, and conforms to a widest scope consistent to principles and novel characteristics disclosed herein.

1. A flexible hard composite coating, comprising an AlCrN transition layer and a nanocomposite layer sequentially disposed on the surface of a substrate, the nanocomposite layer comprising CrON layers and AlON layers sequentially alternately arranged on the surface of the AlCrN transition layer.

2. The flexible hard composite coating according to claim 1, wherein a thickness of each CrON layer and a thickness of each AlON layer are independently 3˜20 nm respectively.

3. The flexible hard composite coating according to claim 1, wherein a quantity of the CrON layers is 10˜50.

4. The flexible hard composite coating according to claim 1, wherein the CrON layer contains 34˜45 at. % of chromium, 12˜18 at. % of oxygen and 40˜50 at. % of nitrogen according to atomic percent.

5. The flexible hard composite coating according to claim 4, wherein the CrON layer comprises a CrN nanocrystalline and Cr2O3 amorphous nanocomposite structure.

6. The flexible hard composite coating according to claim 1, wherein the AlON layer contains 35˜43 at. % of aluminium, 10˜20 at. % of oxygen and 38˜48 at. % of nitrogen according to atomic percent.

7. The flexible hard composite coating according to claim 6, wherein the AlON layer comprises an AIN nanocrystalline and Al2O3 amorphous nanocomposite structure.

8. The flexible hard composite coating according to claim 1, wherein thickness of the AlCrN transition layer is 200˜500 nm.

9. A preparation method of the flexible hard composite coating according to claim 1, comprising:
(1) depositing an AlCrN transition layer on the surface of a substrate; and
(2) sequentially alternately depositing CrON layers and AlON layers on the surface of the AlCrN transition layer, to obtain the flexible hard composite coating.

10. The preparation method coating according to claim 9, wherein both of said depositing and said sequentially alternately depositing comprise high power pulse magnetron sputtering deposition.

11. A coated cutter comprising a cutter substrate and a coating disposed on a surface of the cutter substrate, the coating being a flexible hard composite coating according to claim 1.

12. The flexible hard composite coating according to claim 2, wherein a quantity of the CrON layers is 10˜50.

13. The flexible hard composite coating according to claim 2, wherein the CrON layer contains 34˜45 at. % of chromium, 12˜18 at. % of oxygen and 40˜50 at. % of nitrogen according to atomic percent.

14. The flexible hard composite coating according to claim 13, wherein the CrON layer comprises a CrN nanocrystalline and Cr2O3 amorphous nanocomposite structure.

15. The flexible hard composite coating according to claim 2, wherein the AlON layer contains 35˜43 at. % of aluminium, 10˜20 at. % of oxygen and 38˜48 at. % of nitrogen according to atomic percent.

16. The flexible hard composite coating according to claim 15, wherein the AlON layer comprises an AIN nanocrystalline and Al₂O₃ amorphous nanocomposite structure.

17. A coated cutter comprising a cutter substrate and a coating disposed on a surface of the cutter substrate, the coating being a flexible hard composite coating according to claim 2.

18. A coated cutter comprising a cutter substrate and a coating disposed on a surface of the cutter substrate, the coating being a flexible hard composite coating according to claim 3.

19. A coated cutter comprising a cutter substrate and a coating disposed on a surface of the cutter substrate, the coating being a flexible hard composite coating prepared by a preparation method according to claim 9.

20. A coated cutter comprising a cutter substrate and a coating disposed on a surface of the cutter substrate, the coating being a flexible hard composite coating prepared by a preparation method according to claim 10.
